(19) United States
(12) Patent Application Publication
(10) Pub. No.: US 2024/0281579 A1
(43) Pub. Date: Aug. 22, 2024

(54) INCREMENTAL SEGMENTATION PROCESSING METHOD AND APPARATUS, COMPUTER DEVICE, AND STORAGE MEDIUM

(71) Applicant: S2C Limited, Shanghai (CN)

(72) Inventors: Zhongwei Shao, Shanghai (CN); Jifeng Zhang, Shanghai (CN); Lu Wan, Shanghai (CN)

(21) Appl. No.: 18/567,305

(22) PCT Filed: Oct. 27, 2021
(86) PCT No.: PCT/CN2021/126683

§ 371 Date: Dec. 5, 2023

(30) Foreign Application Priority Data
Jun. 7, 2021 (CN) 202110628384.1

(51) Int. Cl. G06F 30/327

(52) U.S. Cl. CPC G06F 30/327

(57) ABSTRACT

The present invention relates to the field of segmentation algorithms, and provides an incremental segmentation processing method and apparatus, a computer device, and a storage medium. The specific method includes: obtaining and parsing an initial syntax tree structure of an initial design file and a modified syntax tree structure of a modified design file; obtaining initial running data of the initial design file running in the entire process, and configuring a first programmable logic device; comparing the initial syntax tree structure and the modified syntax tree structure to obtain different nodes therebetween; identifying the first programmable logic device and second programmable logic devices according to the different nodes; and performing calculation to obtain the optimal allocation between nodes in a node position distribution state and the second programmable logic devices, and obtaining an incremental segmentation processing result. By means of the processing solution of the present application, a slightly modified design file can be quickly segmented, thereby saving time and improving efficiency.

### TECHNICAL FIELD

The invention relates to the field of segmentation algorithms, in particular to an incremental segmentation processing method, device, computer device, and storage medium.

### BACKGROUND ART

The correctness and performance index of RTL language design or netlist logic in the chip design file must be verified before it is officially put into the factory for chip production. In chip design, programmable logic verification arrays are often used to verify RTL designs written in Verilog/System Verilog/VHDL and other languages. It is necessary to generate a syntax tree inside the computer, flatten the boundary nodes in the syntax tree to the top level and abstract them into hypergraphs. The segmentation algorithm engine divides the nodes into a specified number of different parts on the hypergraphs. Each part is restored to RTL-level design through the process from Hypergraph to Hardware Description Language (HDL), and then the RTL design of each part is logically integrated by using programmable logic devices to generate netlist. After layout and wiring, all FPGAs are powered on at the same time, and AC signals are communicated through interconnection lines between arrays. The logic in the chip design file is verified by listening to different signals on FPGA. Among them, the logic synthesis process will consume a lot of time, and in general, the large-scale design will take dozens of hours, and it will also take even dozens of hours for the layout and wiring of each part of the synthesized netlist in its own FPGA.

However, in the process of logic verification, it is sometimes necessary to modify its design a little to debug the design file, so as to debug errors or optimize performance. This debugging operation is inevitable and frequent. However, even if the user only changes a limited number of operators for debugging, which may be a slight change of one thousandth or one thousandth of the whole design, the whole process of RTL segmentation will have to be repeated, and it will take dozens of hours to consume again, which not only wastes a lot of time and computing resources, but also has extremely low debugging efficiency, and may even affect the production plan of the whole product.

### SUMMARY OF THE INVENTION

Therefore, in order to overcome the shortcomings of the above-mentioned prior art, the present invention provides an incremental segmentation processing method, device, computer device and storage medium that can quickly process a design file with a small amount of modification, thereby saving time and improving efficiency.

In order to achieve the above objectives, the present invention provides an incremental segmentation processing method, including the following steps: obtain an initial design file and a modified design file of a programmable logic verification array, and parse the initial syntax tree structure of the initial design file and the modified syntax tree structure of the modified design file: When it is determined that the difference between the initial syntax tree structure and the modified syntax tree structure is not higher than the preset increment threshold, obtain the initial operation data of the initial design file running in the whole process, and configure the programmable logic device storing the initial operation data as the first programmable logic device: compares the different nodes between the initial syntax tree structure and the modified syntax tree structure: Identifying the first programmable logic device and the second programmable logic device in the programmable logic verification array according to the different node, wherein the node in the modified syntax tree structure executed by the second programmable logic device is not operated and save the operation data: According to the comparison result between the number of different nodes and the preset node threshold and the node position distribution state of each second programmable logic device, calculate the optimal allocation between nodes and second programmable logic devices in the node position distribution state, and obtain the incremental segmentation processing result.

In one embodiment, comparing the different nodes between the initial syntax tree structure and the modified syntax tree structure includes: performing breadth first recursive traversal search downward from the top nodes in the initial syntax tree structure and the modified syntax tree structure, respectively, and obtaining the initial module and the modification module respectively corresponding to the operation objects in the same position in the two syntax tree structures: determine whether the initial module and the modification module have different logical contents or connection relations: When it is determined that there are differences, the modification module is marked as a difference module, and the different node and the reserved node in the difference module are obtained by comparing the nodes in the initial module and the modification module.

In one embodiment, identifying a first programmable logic device and a second programmable logic device in a programmable logic verification array according to different nodes includes: respectively determining an initial division boundary of an initial syntax tree structure and a modified segmentation boundary of a modified syntax tree structure through a boundary search module according to nodes with designated fixed segmentation positions: Traversing each node distributed on each programmable logic device in the initial dividing boundary, and comparing with the nodes in the modified dividing boundary one by one according to the hierarchical path of the nodes on the programmable logic device: Configuring the programmable logic device as a second programmable logic device when it is determined that there is a different node in the programmable logic device: When it is determined that there is no different node in the programmable logic device, the programmable logic device is set as the first programmable logic device.

In one embodiment, according to the comparison result between the number of different nodes and the preset node threshold and the node position distribution state of each second programmable logic device, calculate the optimal allocation between nodes and second programmable logic devices in the node position distribution state, including: determining whether the number of different nodes in the second programmable logic device exceeds the preset node threshold: When it is determined to be exceeded, the optimal allocation between the nodes and the second programmable logic devices in the node position distribution state is calculated by combining the node position distribution state of each second programmable logic device with the clustering division method: When it is determined that it is not exceeded, the greedy division method is adopted to combine the node position distribution state of each second programmable logic device, and calculate the optimal allocation between the node and the second programmable logic device under the node position distribution state.

In one embodiment, adopt the greedy division method to combine the node position distribution state of each second programmable logic device to calculate to obtain the optimal allocation between the nodes and the second programmable logic device in the node position distribution state, including: obtaining the total number of second programmable logic devices and establishing a priority queue corresponding to the total number, wherein the priority queue is used for storing the initial weight of different nodes, and the initial weight is used for representing the cutting caused by the allocation of the different nodes to the second programmable logic devices. Calculating the modified weight allocated by each different node to each second programmable logic device, and replacing the stored initial weight: Allocating the different node with the smallest modification weight in the priority queue to a second programmable logic device, and deleting the different node from the priority queue: Repeatedly calculating the modified weights allocated by different nodes to the operation of the second programmable logic device, and allocating the different nodes until the different nodes are completely allocated, at this time the node layout of the second programmable logic device is optimal allocation.

In one embodiment, the method further includes controlling the second programmable logic device to execute the allocated different node according to the optimal allocation, and configuring the second programmable logic device storing the operation data for operating the modified syntax tree structure as the first programmable logic device.

The invention also provides an incremental segmentation processing device, which includes a file analysis acquisition module for acquiring an initial design file and a modified design file of a programmable logic verification array, and analyzing an initial syntax tree structure of the initial design file and a modified syntax tree structure of the modified design file: a syntax tree running module is used for acquiring initial running data of running the initial design file in the whole process when it is determined that the difference between the initial syntax tree structure and the modified syntax tree structure is not higher than a preset increment threshold, and configuring a programmable logic device storing the initial running data as a first programmable logic device: a comparison module for comparing the different nodes between the initial syntax tree structure and the modified syntax tree structure: a device identification module is used for identifying the first programmable logic device and the second programmable logic device in the programmable logic verification array according to the different node, and the operation data of the node in the modified syntax tree structure executed by the second programmable logic device is not saved: a node allocation module is used for calculating the optimal allocation between the nodes and the second programmable logic devices in the node position distribution state according to the comparison result between the number of the different nodes and a preset node threshold and the node position distribution state of each second programmable logic device: a data operation module, configured to control the second programmable logic device to execute the allocated different node according to the optimal allocation, and set the second programmable logic device storing the operation data for operating the modified syntax tree structure as the first programmable logic device: And a verification module is used for verifying all the first programmable logic devices and obtaining the incremental segmentation processing result.

The invention also provides a computer device, including a memory and a processor, wherein the memory stores a computer program, and the processor realizes the steps of the method when executing the computer program.

The invention also provides a computer readable storage medium, on which a computer program is stored, which, when executed by a processor, realizes the steps of the above method.

Compared with the prior art, the invention has the advantages that only a few changed programmable logic devices are re-divided, logically integrated, laid out and wired by an incremental processing method, and calculate the incremental segmentation processing results of the programmable logic devices, and reduce the secondary operation processing of unchanged programmable logic device, so that not only save time and calculation resources, but also improve the debugging efficiency, and accelerate the production plan of the whole product.

### BRIEF DESCRIPTION OF THE DRAWINGS

In order to explain the technical scheme of the embodiment of the application more clearly, the drawings needed in the embodiment will be briefly introduced below. Obviously, the drawings described below are only some embodiments of the application. For ordinary people in the field, other drawings can be obtained according to these drawings without creative work.

FIG. 1 is a flowchart of an incremental segmentation processing method in one embodiment;

FIG. 2 is a flowchart of incremental segmentation processing steps in one embodiment:

FIG. 3 is a structural block diagram of an incremental segmentation processing device in one embodiment:

FIG. 4 is an internal structure diagram of a computer device in one embodiment.

### DETAILED DESCRIPTION

The embodiments of the present application will be described in detail with the drawings.

The following describes the implementation of the application through specific embodiments, and those skilled in the art can easily understand other advantages and effects of the application from the contents disclosed in this specification. Obviously, the described embodiment is only a part of the embodiment of this application, not the whole embodiment. This application can also be implemented or applied through different specific embodiments, and the details in this specification can be modified or changed based on different viewpoints and applications without departing from the spirit of this application. It should be noted that the following embodiments and features in the embodiments can be combined with each other without conflict. Based on the embodiments in this application, all other embodiments obtained by ordinary technicians in this field without creative work belong to the protection scope of this application.

It is noted that various aspects of the embodiments within the scope of the appended claims are described below. It should be obvious that the aspects described herein can be embodied in a wide variety of forms, and any specific structure and/or function described herein is merely illustrative. Based on this application, those skilled in the art should understand that one aspect described herein can be implemented independently of any other aspect, and two or more of these aspects can be combined in various ways. For example, devices and/or practice methods may be implemented using any number and aspects set forth herein. In addition, the apparatus and/or the method may be implemented using other structures and/or functionalities than one or more of the aspects set forth herein.

It should also be noted that the diagrams provided in the following examples only illustrate the basic concept of this application in a schematic way, and only the components related to this application are shown in the diagrams, instead of being drawn according to the number, shape and size of components in actual implementation. In actual implementation, the types, numbers and proportions of components can be changed at will, and the layout of components may be more complicated.

In addition, in the following description, specific details are provided to facilitate a thorough understanding of the examples. However, it will be understood by those skilled in the art that aspects may be practiced without these specific details.

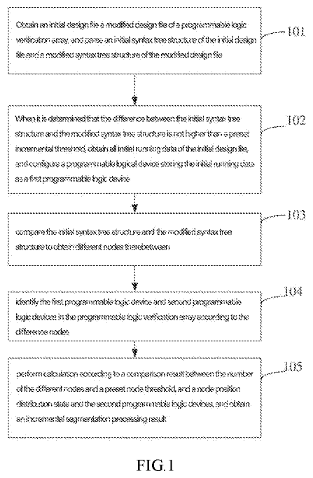

As shown in FIG. 1, the embodiment of the application provides an incremental segmentation processing method, which can be applied to a terminal or a server. The terminal can be but not limited to various personal computers, notebook computers, smart phones, tablet computers and portable intelligent devices, and the server can be realized by an independent server or a server cluster composed of multiple servers. The method includes the following steps:

Step 101: Obtain the initial design file and the modified design file of the programmable logic verification array, and parse the initial syntax tree structure of the initial design file and the modified syntax tree structure of the modified design file.

The design file is used to describe the structure of each circuit node of the circuit system and the connection relationship between the circuit nodes. The design file contains many logic modules, there are nested or parallel relations between logical program modules, and each logic module corresponds to each circuit node of the circuit system. A circuit node may be one or more electronic components. The initial design file is the design file before modification, and the programmable logic device can store the running parameters, device execution data and so on after the initial design file is converted into the initial syntax tree structure. The modified design file is a modified design file, which is used to replace the initial design file and its initial running data stored in the programmable logic device.

Programmable logic verification array is an element array composed of multiple programmable logic devices. In one embodiment, the programmable logic device may be an FPGA. The server can obtain the initial design file and the modified design file of the programmable logic verification array, and analyze the initial syntax tree structure of the initial design file and the modified syntax tree structure of the modified design file. The server can parse the initial design file, and save the initial syntax tree structure Tree_Ref in the memory, and save the segmentation result of its node allocation position as design.fpga.out. Ref The server can parse the modified design file Design_Main to get the modified syntax tree structure Tree_Main of the modified design file.

Step 102: When it is determined that the difference between the initial syntax tree structure and the modified syntax tree structure is not higher than the preset increment threshold, obtain all initial operation data of the initial design file, and configure the programmable logic device storing the initial operation data as the first programmable logic device.

The server first determines whether the difference between the initial syntax tree structure and the modified syntax tree structure is greater than the preset incremental threshold, and the server determines whether the difference between Design_Main and Design_Ref is greater than the preset incremental threshold. The preset incremental threshold can be calculated according to the incremental threshold evaluation module or determined according to the parameters input by the user, preferably 15%. When the server determines that the difference between Design_Main and Design_Ref is greater than the preset incremental threshold, it abandons the incremental processing method and directly re-executes the complete process according to the brand-new user design; when the server determines that the difference between Design_Main and Design_Ref is not more than 15%, the incremental processing step is performed.

The initial running data is the data of each FPGA finally obtained by the server through a full process processing of the initial design file. The full process processing refers to the server's operations of converting HDL to hypergraph, re-segmentation, converting hypergraph to HDL, re-logically synthesizing each part of the design, and laying out and wiring according to the initial design file. The server obtains the initial operation data of running the initial design file in the whole process. The server sets the programmable logic device storing the initial operation data as the first programmable logic device, and the initial segmentation result can be used as the input reference for subsequent modified design file.

Step 103: compares the different nodes between the initial syntax tree structure and the modified syntax tree structure.

The server compares the different nodes between the initial syntax tree structure and the modified syntax tree structure. The Server compare and search for the different nodes Design_Ref and Tree_Main of two main trees. Specifically, the different nodes include three types: newly added nodes, deleting nodes and modified nodes. The node here corresponds to the Module in the design. Module is a template containing the user's design logic. In fact, the node in the syntax tree is an instance of the Module. Modified nodes are those nodes that undergo logical content or internal connection relationship changes in their corresponding modules or external connection relationship changes, which can be called polluted node. The newly added nodes are the node that are added to the modified syntax tree structure compared to the original syntax tree structure. The deleted nodes are nodes that reduces the number of nodes in the syntax tree compared to the original syntax tree. Invariant nodes are those nodes that don't undergo logical content or internal connection relationship changes in their corresponding modules and external connection relationship has not changed, which can be called clean node. If the child node is a newly added or deleted node, at least one of its ancestor nodes is a modified node, because the newly added and deletion must be reflected in the change of the logical content or connection relationship of the module corresponding to an ancestor node: if the parent node is a modified node, the logical content or connection relationship of its descendants may be affected by it and become a change node: If a leaf node is a clean node, all its direct ancestor nodes must be clean nodes.

Step 104, identify the first programmable logic device and the second programmable logic device in the array according to the different node, and the node in the modified syntax tree structure executed by the second programmable logic device is not operated and saves the running data.

The first programmable logic device has no change in the design logic (that is, the nodes allocate to the programmable logic device are all invariant nodes, no different nodes), including the logic content and internal connection relations, external connection relations, it does not need to be recompiled (logic synthesis and layout), called fix FPGA. The second programmable logic device is the logic content or the internal connection relationship or the external connection relationship changes, the need to re-logically synthesis and layout, the need to consume time and computing resources, at this time the recompilation of programmable logic devices is inevitable, called free FPGA. The server allocates nodes in the modified syntax tree structure to the second programmable logic device, and the node layout of the second programmable logic device contains at least one different node. Due to the server does not control the second programmable logic device to parse and run the modified design file, the nodes in the modified syntax tree executed by the second programmable logic device are not run and save the running data.

The server identifies the first programmable logic device and the second programmable logic device in the array according to the different node, and the second programmable logic device executes the modification syntax tree whose node is not run and saves the running data. The server recognizes free FPGAs and fix FPGAs, and no processing is required for fix FPGAs, thus saving the recompilation time for each node located on the fix FPGA. The free FPGAs is the new array to be allocated.

Step 105: According to the comparison result between the number of different nodes and the preset node threshold and the node position distribution state of each second programmable logic device, calculate the optimal allocation between nodes and second programmable logic devices in the node position distribution state, and obtain the incremental segmentation processing result.

Boundary_Main is the segmentation boundary determined by the server in modifying the syntax tree structure by using the boundary search module. The subtree below each node on the segmentation boundary is defined as a black box, and the leaf nodes of the black-boxed syntax tree are the segmentation boundary nodes, and the segmentation boundary nodes will participate in the division as a whole. The server still allocates the boundary nodes in the Boundary_Main of the Tree_Main to the original FPGA: the server allocates the different nodes in the Boundary_Main of the Tree_Main as free nodes to be allocated to the second programmable logic device. According to the comparison result between the number of different nodes and the preset node threshold and the node position distribution state of each second programmable logic device, the server calculates the optimal allocation between the node free nodes and the second programmable logic device free FPGAs in the node position distribution state, and obtains the incremental segmentation processing result.

In one embodiment, the method further includes controlling the second programmable logic device to execute the allocated different node according to the optimal allocation, and configuring the second programmable logic device storing the operation data for operating the modified syntax tree structure as the first programmable logic device.

The server can verify the incremental segmentation processing results, and the server can control the FPGA to run the whole process according to the incremental segmentation processing results to finally get the data of each FPGA. The server controls the second programmable logic device to execute the allocated different node according to the optimal allocation, and sets the second programmable logic device storing the operation data of the modified syntax tree structure as the first programmable logic device. The server compiles free FPGA according to the optimal allocation, including logic synthesis and layout, and does not do any operation on the logic on fix FPGA. Therefore, compared with all FPGA recompilation in the prior art, the time saved is considerable.

The above incremental segmentation processing method, through an incremental segmentation processing method, only a small number of changed programmable logic devices are re-segmentation, logically integrated, laid out and wired, and the incremental segmentation processing results of the programmable logic devices are calculated, and the secondary operation processing of unchanged programmable logic devices is reduced, so that not only time and calculation resources are saved, but also improving the debugging efficiency and accelerating the production plan of the entire product.

In one embodiment, comparing the different nodes between the initial syntax tree structure and the modified syntax tree structure includes: performing breadth first recursive traversal search downward from the top nodes in the initial syntax tree structure and the modified syntax tree structure, respectively, and obtaining the initial module and the modification module respectively corresponding to the operation objects in the same position in the two syntax tree structures; determine whether the initial module and the modification module have different logical contents or connection relations: When it is determined that there are differences, the modification module is marked as a difference module, and the different node and the reserved node in the difference module are obtained by comparing the nodes in the initial module and the modification module.

The server first marks all nodes in Design_Ref and Tree_Main as invariant nodes; Starting from the top node of the two trees, respectively, the breadth first (BFS) recursive traversal search is carried out downward, to find the initial module module_Ref and the modification module module_Main corresponding to the instance nodes in the same position in the structure of the two syntax trees respectively. By inputting the initial module and the modification module into the grammar comparator, the server compares whether the two modules have different logical contents or connection relationships. When it is determined that there are differences, the modification module is marked as a difference module, and the node corresponding to the difference module is marked as a polluted node, and it is determined that the nodes in the subtree below the polluted node may be changed nodes, all of which are directly marked as polluted nodes, so that all nodes can be processed quickly without further parsing grammar in depth and detail. The server continues to search the subtree from the polluted node, and checks and marks the different nodes between the initial module and the modification module in Tree_Main and Tree_Ref until all the leaf nodes in the tree are marked: Finally, the leaf node sets (i.e., segmentation boundary sets) of the two syntax trees are output, wherein the segmentation boundary set of the initial syntax tree is Boundary Ref, and the segmentation boundary set of the modified syntax tree is Boundary_Main, and each node carries tag information.

In one embodiment, identifying a first programmable logic device and a second programmable logic device in a programmable logic verification array according to different nodes includes: respectively determining an initial division boundary of an initial syntax tree structure and a modified segmentation boundary of a modified syntax tree structure through a boundary search module according to nodes with designated fixed segmentation positions: Traversing each node distributed on each programmable logic device in the initial dividing boundary, and comparing with the nodes in the modified dividing boundary one by one according to the hierarchical path of the nodes on the programmable logic device: Configuring the programmable logic device as a second programmable logic device when it is determined that there is a different node in the programmable logic device: When it is determined that there is no different node in the programmable logic device, the programmable logic device is set as the first programmable logic device.

The server determines the initial segmentation boundary of the initial syntax tree structure and the modified segmentation boundary of the modified syntax tree structure respectively through the boundary search module according to the nodes with fixed segmentation positions. The initial segmentation result design.fpga.out.Ref not only contains the initial segmentation boundary and the node allocation result, but also contains the black box formed by the subtree under each node on the initial segmentation boundary, and the server can generate the initial segmentation result according to the initial segmentation boundary. The modified Boundary_Main contains a set of modified boundary nodes, and the server can generate modified segmentation results according to the modified boundary.

The server traverses each node on each programmable logic device in the initial segmentation result design.fpga.out. Ref, and compares it with the nodes in the modified segmentation boundary Boundary_Main one by one according to the hierarchical path of the nodes on the programmable logic device.

When it is determined that there is a different node in the programmable logic device, the server sets the programmable logic device as the second programmable logic device free FPGA: When it is determined that there is no different node in the programmable logic device, the server sets the programmable logic device as the first programmable logic device fix FPGA.

In one embodiment, according to the comparison result between the number of different nodes and the preset node threshold and the node position distribution state of each second programmable logic device, calculate the optimal allocation between nodes and second programmable logic devices in the node position distribution state, including: determining whether the number of different nodes in the second programmable logic device exceeds the preset node threshold: When it is determined to be exceeded, the optimal allocation between the nodes and the second programmable logic devices in the node position distribution state is calculated by combining the node position distribution state of each second programmable logic device with the clustering division method: When it is determined that it is not exceeded, the greedy division method is adopted to combine the node position distribution state of each second programmable logic device, and calculate the optimal allocation between the node and the second programmable logic device under the node position distribution state.

The server determines whether the number of different nodes in the second programmable logic device exceeds a preset node threshold. The preset node threshold comes from the threshold evaluation module of segmentation algorithm, which is used to select different segmentation algorithms according to the number of nodes to be segmented. Wherein, clustering segmentation algorithm is suitable for the division of large-scale nodes, with relatively high time complexity and better segmentation effect (that is, the sum of segmentation cost weights of the segmented network): Greedy fast segmentation method is suitable for fast segmentation of a small number of nodes, with low time complexity and satisfactory segmentation effect. When it is determined to be exceeded, the server adopts a clustering division method and combines the node position distribution state of each second programmable logic device to calculate the optimal allocation between the node and the second programmable logic device under the node position distribution state: When it is determined that it is not exceeded, the server uses greedy division method to combine the node position distribution state of each second programmable logic device to calculate the optimal allocation between the node and the second programmable logic device under the node position distribution state.

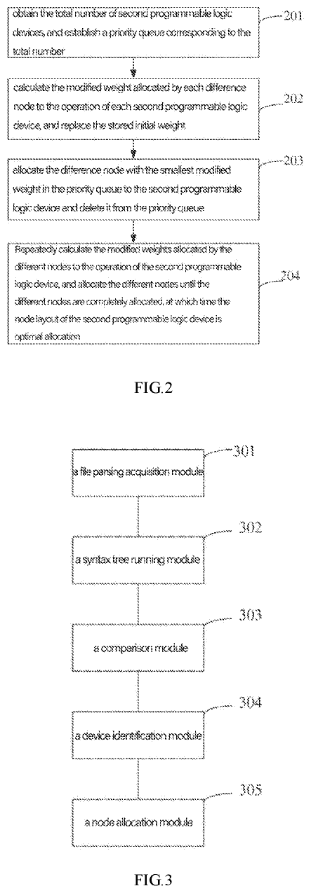

As shown in FIG. 2, in one embodiment, the greedy division method is used to calculate the optimal allocation between nodes and second programmable logic devices in the node position distribution state, including the following steps:

Step 201: obtain the total number of second programmable logic devices, and establish a priority queue corresponding to the total number. The priority queue is used to store the initial weight of different nodes, and the initial weight is used to represent the cutting cost caused by the allocation of the different nodes to the second programmable logic devices.

The server obtains the total number of second programmable logic devices, and establishes a priority queue corresponding to the total number. The priority queue is used to store the initial weight of different nodes, and the initial weight is used to represent the cutting cost caused by the allocation of the different nodes to the second programmable logic devices. In one embodiment, the weight is the cut size cost. Assuming that the number of free FPGAs is num_FPGA, then establish num_FPGA priority_queue, which will store the cost of cut size growth caused by each free node being allocated to each free FPGA. For example, num_FPGA=4, then there will be four priority queues, and the value of a free node in priority_queue_1 represents the cut size cost caused by the allocation of the free node on FPGA No. 1. The distribution of FPGA nodes is defined as FPGA_distribution, and the initial state of FPGA distribution is the distribution of initial distribution positions of nodes marked as invariant in Boundary_Main of Tree_Main.

Queue is a first-in-first-out data structure, and priority queue is a more advanced queue. The elements in it are given priority. When the elements are popped up, it is not first in, first out, but the highest priority first out. In this embodiment, the priority is cut size, the smaller the cut size, the higher the priority, and each element also corresponds to a specific free node. Cut size is the sum of the weights of the cut edges (net) after the graph is segmented. The smaller the weight value after the segmentation, the better the segmentation effect.

Step 202: calculate the modified weight allocated by each different node to the operation of each second programmable logic device, and replace the stored initial weight.

The server calculates the modified weight allocated by each different node to the operation of each second programmable logic device, and replaces the stored initial weight. The server recalculates the cut size caused by each free node being allocated to each free FPGA in the existing FPGA_distribution, and updates the cut size cost of the corresponding node in the replacement priority queue.

Step 203: allocate the different node with the smallest modified weight in the priority queue to the second programmable logic device and delete it from the priority queue.

The server allocates the different node with the smallest modified weight in the priority queue to the second programmable logic device and deletes it from the priority queue. The server pops up the first element of each queue, and the first element of each queue takes the cut size cost minimum element to obtain the free node corresponding to the element and the number of the queue, allocate the node to the logical array with FPGA number corresponding to the priority queue, complete the allocation of the free node, and update the allocation position of the free node to FPGA_distribution. The server deletes this node from the free nodes collection and records the cut size cost paid for this allocation.

Step 204: Repeatedly calculate the modified weights allocated by the different nodes to the operation of the second programmable logic device, and allocate the different nodes until the different nodes are completely allocated, at which time the node layout of the second programmable logic device is optimal allocation.

The server repeatedly calculates the modified weights allocated by the different nodes to the operation of the second programmable logic device, and allocates the different nodes until the different nodes are completely distributed, at which time the node layout of the second programmable logic device corresponds to the optimal allocation between the nodes and the second programmable logic device.

In one embodiment, as shown in FIG. 3, an incremental segmentation processing device is provided, which includes a file parsing acquisition module 301, a syntax tree running module 302, a comparison module 303, a device identification module 304 and a node allocation module 305.

The file parsing acquisition module 301 is used to obtain the initial design file and the modified design file of the programmable logic verification array, and parse the initial syntax tree structure of the initial design file and the modified syntax tree structure of the modified design file.

The syntax tree running module 302 is used to obtain the initial running data of the initial design file for full-flow operation when it is determined that the difference between the initial syntax tree structure and the modified syntax tree structure is not higher than the preset incremental threshold, and set the programmable logic device storing the initial running data as the first programmable logic device.

The comparison module 303 is used to compare the initial syntax tree structure and modify the different nodes between the syntax tree structures.

The device identification module 304 is used to identify the first programmable logic device and the second programmable logic device in the programmable logic verification array according to the different nodes, and the nodes in the modified syntax tree structure executed by the second programmable logic device are not operated and save the operation data.

The node allocation module 305 is configured to calculate the optimal allocation between the nodes and the second programmable logic devices in the node position distribution state according to the comparison result between the number of different nodes and the preset node threshold and the node position distribution state of each second programmable logic device, and obtain the incremental segmentation processing result.

In one embodiment, the comparison module 303 includes:
an acquisition unit, configured to perform breadth first recursive traversal search downward from the top nodes in the initial syntax tree structure and the modified syntax tree structure, respectively, and acquire the initial module and the modification module respectively corresponding to the operation objects in the same position in the two syntax tree structures.
a determining unit is used for determining whether the initial module and the modification module have different logical contents or connection relations.
a marking unit, configured to mark the modification module as a difference module when it is determined that there are differences, and obtain a different node and a reserved node in the difference module by comparing the nodes in the initial module and the modification module.

In one embodiment, the device identification module 304 includes:
a segmentation unit is used for respectively determining the initial segmentation boundary of the initial syntax tree structure and the modified segmentation boundary of the modified syntax tree structure through the boundary searching module according to the nodes with designated fixed segmentation positions.
a comparing unit is used for traversing each node distributed on each programmable logic device in the initial dividing boundary and comparing with the nodes in the modified dividing boundary one by one according to the hierarchical paths of the nodes on the programmable logic device.
a configuring unit is used for configuring the programmable logic device as a second programmable logic device when it is determined that there is a different node in the programmable logic device: When it is determined that there is no different node in the programmable logic device, the programmable logic device is set as the first programmable logic device.

In one embodiment, the node allocation module 305 includes:
a node determining unit is used for determining whether the number of different nodes in the second programmable logic device exceeds a preset node threshold.
an allocation selection unit is used for calculating the optimal allocation between the nodes and the second programmable logic devices in the node position distribution state by adopting a clustering division method in combination with the node position distribution state of each second programmable logic device when the decision is exceeded: When it is determined that it is not exceeded, the greedy division method is adopted to combine the node position distribution state of each second programmable logic device, and the optimal allocation between the node and the second programmable logic device under the node position distribution state is calculated.

In one embodiment, the node allocation module 305 includes:
a queue generating unit is used for acquiring the total number of second programmable logic devices and establishing a priority queue corresponding to the total number, and the priority queue is used for storing the initial weight of each second programmable logic device running each allocated different node.
a weight replacement unit is used for calculating the modified weight allocated by each different node to the operation of each second programmable logic device and replacing the stored initial weight.
a node allocation unit is used for allocating the different node with the smallest modified weight in the priority queue to the second programmable logic device and deleting it from the priority queue.
a repeating unit is used for repeatedly calculating the modification weights allocated by the different nodes to the operation of the second programmable logic device, and distributing the different nodes until the different nodes are completely allocated, at this time the node layout of the second programmable logic device is optimal allocation.

For the specific definition of the incremental segmentation processing device, please refer to the definition of the incremental segmentation processing method above, and will not be repeated here. Each module in the above incremental segmentation processing device can be realized in whole or in part by software, hardware and their combinations. The above modules can be embedded in or independent of the processor in the computer equipment in the form of hardware, and can also be stored in the memory in the computer equipment in the form of software, so that the processor can call and execute the operations corresponding to the above modules.

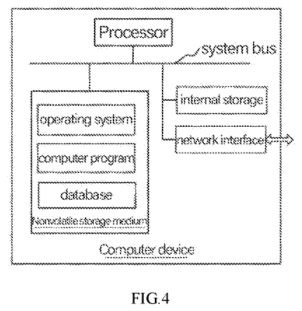

In one embodiment, a computer device is provided, which may be a server, and its internal structure diagram may be as shown in FIG. 4. The computer equipment includes a processor, a memory, a network interface and a database connected through a system bus. Wherein the processor of the computer device is used for providing computing and control capabilities. The memory of the computer device includes a nonvolatile storage medium and an internal memory. The nonvolatile storage medium stores an operating system, a computer program and a database. The internal memory provides an environment for the operation of the operating system and computer programs in the nonvolatile storage medium. The database of the computer equipment is used to store incremental segmentation processing data. The network interface of the computer equipment is used to communicate with external terminals through network connection. The computer program, when executed by a processor, implements an incremental segmentation processing method.

Those skilled in the art can understand that the structure shown in FIG. 4 is only a block diagram of a part of the structure related to the scheme of the present application, and does not constitute a limitation on the computer equipment to which the scheme of the present application is applied. The specific computer equipment may include more or less components than those shown in the figure, or combine some components, or have different component arrangements.

In one embodiment, a computer device is provided, which includes a memory and a processor, wherein the memory stores a computer program, and when the processor executes the computer program, the following steps are realized: acquiring an initial design file and a modified design file of a programmable logic verification array, and analyzing the initial syntax tree structure of the initial design file and modifying the modified syntax tree structure of the design file: When it is determined that the difference between the initial syntax tree structure and the modified syntax tree structure is not higher than a preset incremental threshold, initial operation data of the initial design file is obtained for full-flow operation, and a programmable logic device storing the initial operation data is set as a first programmable logic device: Comparing the initial syntax tree structure and modifying the different nodes between the syntax tree structures: Identifying a first programmable logic device and a second programmable logic device in a programmable logic verification array according to the different nodes, wherein the nodes in the modified syntax tree structure executed by the second programmable logic device are not operated and the operation data are saved; According to the comparison result between the number of different nodes and the preset node threshold and the node position distribution state of each second programmable logic device, the optimal allocation between nodes and second programmable logic devices in the node position distribution state is calculated; According to the optimal allocation, control the second programmable logic device to execute the allocated different node, and obtain the incremental segmentation processing result.

In one embodiment, when a processor executes a computer program, comparing the initial syntax tree structure and modifying the different nodes between the syntax tree structures, includes: performing breadth first recursive traversal search downward from the top nodes in the initial syntax tree structure and the modified syntax tree structure, respectively, and acquiring the initial module and the modification module respectively corresponding to the operation objects in the same position in the two syntax tree structures: determining whether the initial module and the modification module have different logical contents or connection relations: When it is determined that there are differences, the modification module is marked as a difference module, and obtain the different node and the reserved node in the difference module by comparing the nodes in the initial module and the modification module.

In one embodiment, when a processor executes a computer program, realize the identification of a first programmable logic device and a second programmable logic device in a programmable logic verification array according to different nodes, which includes the following steps of: respectively determining an initial division boundary of an initial syntax tree structure and a modified segmentation boundary of a modified syntax tree structure according to nodes with fixed segmentation positions: Traversing each node distributed on each programmable logic device in the initial dividing boundary, and comparing with the nodes in the modified dividing boundary one by one according to the hierarchical path of the nodes on the programmable logic device; Configuring the programmable logic device as a second programmable logic device when it is determined that there is a different node in the programmable logic device; When it is determined that there is no different node in the programmable logic device, the programmable logic device is set as the first programmable logic device.

In one embodiment, when a processor executes a computer program, calculate to obtain the optimal allocation between nodes and second programmable logic devices in the node position distribution state according to the comparison result between the number of different nodes and a preset node threshold and the node position distribution state of each second programmable logic device, including: determining whether the number of different nodes in the second programmable logic device exceeds the preset node threshold: When it is determined to be exceeded, through combining the node position distribution state of each second programmable logic device with the clustering division method, calculate to obtain the optimal allocation between the nodes and the second programmable logic devices in the node position distribution state: When it is determined that it is not exceeded, adopt the greedy division method to combine the node position distribution state of each second programmable logic device, and calculate to obtain the optimal allocation between the node and the second programmable logic device under the node position distribution state.

In one embodiment, when a processor executes a computer program, adopt the greedy division method to combine the node position distribution state of each second programmable logic device to calculate to obtain the optimal allocation between the nodes and the second programmable logic device in the node position distribution state, including: obtaining the total number of second programmable logic devices and establishing a priority queue corresponding to the total number, wherein the priority queue is used for storing the initial weight of different nodes, and the initial weight is used for representing the cutting caused by the allocation of the different nodes to the second programmable logic devices. Calculating the modified weight allocated by each different node to each second programmable logic device, and replacing the stored initial weight: Allocating the different node with the smallest modification weight in the priority queue to a second programmable logic device, and deleting the different node from the priority queue: Repeatedly calculating the modified weights allocated by different nodes to the operation of the second programmable logic device, and allocating the different nodes until the different nodes are completely allocated, at this time the node layout of the second programmable logic device is optimal allocation.

In one embodiment, when the processor executes the computer program, the method realized further includes controlling the second programmable logic device to execute the allocated different node according to the optimal allocation, and configuring the second programmable logic device storing the operation data for operating the modified syntax tree structure as the first programmable logic device.

In one embodiment, when execute the computer program by a processor, a computer readable storage medium is provided, on which a computer program is stored, and realize the following steps: acquiring an initial design file and a modified design file of a programmable logic verification array, and parsing the initial syntax tree structure of the initial design file and modifying the modified syntax tree structure of the design file: When it is judged that the difference between the initial syntax tree structure and the modified syntax tree structure is not higher than a preset incremental threshold, initial operation data of the initial design file is obtained for full-flow operation, and a programmable logic device storing the initial operation data is set as a first programmable logic device: Comparing the initial syntax tree structure and modifying the different nodes between the syntax tree structures: Identifying a first programmable logic device and a second programmable logic device in a programmable logic verification array according to the different nodes, wherein the nodes in the modified syntax tree structure executed by the second programmable logic device are not operated and the operation data are saved: According to the comparison result between the number of different nodes and the preset node threshold and the node position distribution state of each second programmable logic device, calculate to obtain the optimal allocation between nodes and second programmable logic devices in the node position distribution state, and obtain the incremental segmentation processing result.

In one embodiment, the identification of the first programmable logic device and the second programmable logic device in the programmable logic verification array according to the different nodes is realized when the computer program is executed by the processor, which includes the following steps: respectively determining the initial division boundary of the initial syntax tree structure and the modified segmentation boundary of the modified syntax tree structure according to the nodes with fixed segmentation positions: Traversing each node distributed on each programmable logic device in the initial dividing boundary, and comparing with the nodes in the modified dividing boundary one by one according to the hierarchical path of the nodes on the programmable logic device: Configuring the programmable logic device as a second programmable logic device when it is determined that there is a different node in the programmable logic device: When it is determined that there is no different node in the programmable logic device, the programmable logic device is set as the first programmable logic device.

In one embodiment, when a computer program is executed by a processor, calculate to obtain the optimal allocation between nodes and second programmable logic devices in the node position distribution state according to the comparison result between the number of different nodes and a preset node threshold and the node position distribution state of each second programmable logic device, including: determining whether the number of different nodes in the second programmable logic device exceeds the preset node threshold: When it is determined to be exceeded, calculate to obtain the optimal allocation between the nodes and the second programmable logic devices in the node position distribution state by combining the node position distribution state of each second programmable logic device with the clustering division method: When it is determined that it is not exceeded, adopt the greedy division method to combine the node position distribution state of each second programmable logic device, and calculate to obtain the optimal allocation between the node and the second programmable logic device under the node position distribution state.

In one embodiment, when a computer program is executed by a processor, calculate to obtain an optimal allocation between nodes and second programmable logic devices in the node position distribution state is d by combining the greedy division method with the node position distribution state of each second programmable logic device, including: obtaining the total number of second programmable logic devices and establishing a priority queue corresponding to the total number, wherein the priority queue is used for storing the initial weight of different nodes, and the initial weight is used for representing the cutting cost caused by the distribution of the different nodes to the second programmable logic devices: Calculating the modified weight allocated by each different node to each second programmable logic device, and replacing the stored initial weight: The different node with the smallest modified weight in the priority queue is allocated to the second programmable logic device and then deleted from the priority queue: Repeatedly calculating the modified weights allocated by different nodes to the operation of the second programmable logic device, and allocating the different nodes until the different nodes are completely allocated, at this time the node layout of the second programmable logic device is optimal allocation.

In one embodiment, the method realized when the computer program is executed by the processor further includes controlling the second programmable logic device to execute the allocated different node according to the optimal allocation, and configuring the second programmable logic device storing the operation data for operating the modified syntax tree structure as the first programmable logic device.

The above is only the specific implementation of this application, but the protection scope of this application is not limited to this. Any change or replacement that can be easily thought of by a person familiar with this technical field within the technical scope disclosed in this application should be covered by this application. Therefore, the protection scope of this application should be based on the protection scope of the claims.

1. An incremental segmentation processing method, characterized in that, including:
obtaining an initial design file and a modified design file of a programmable logic verification array, and parse the initial syntax tree structure of the initial design file and the modified syntax tree structure of the modified design file;
when it is determined that the difference between the initial syntax tree structure and the modified syntax tree structure is not higher than the preset increment threshold, obtaining the initial operation data of the initial design file running in the whole process, and configure the programmable logic device storing the initial operation data as the first programmable logic device;
comparing the different nodes between the initial syntax tree structure and the modified syntax tree structure;
Identifying the first programmable logic device and the second programmable logic device in the programmable logic verification array according to the different node, wherein the node in the modified syntax tree structure executed by the second programmable logic device is not operated and save the operation data;
According to the comparison result between the number of different nodes and the preset node threshold and the node position distribution state of each second programmable logic device, calculate the optimal allocation between nodes and second programmable logic devices in the node position distribution state, and obtain the incremental segmentation processing result.

2. The incremental segmentation processing method according to claim 1, characterized in that,
comparing the different nodes between the initial syntax tree structure and the modified syntax tree structure, including:
performing breadth first recursive traversal search downward from the top nodes in the initial syntax tree structure and the modified syntax tree structure, respectively, and obtaining the initial module and the modification module respectively corresponding to the operation objects in the same position in the two syntax tree structures;
determining whether the initial module and the modification module have different logical contents or connection relations;
when it is determined that there are differences, the modification module is marked as a difference module, and the different node and the reserved node in the difference module are obtained by comparing the nodes in the initial module and the modification module.

3. The incremental segmentation processing method according to claim 1, characterized in that,
identifying a first programmable logic device and a second programmable logic device in a programmable logic verification array according to different nodes, including:
respectively determining an initial division boundary of an initial syntax tree structure and a modified segmentation boundary of a modified syntax tree structure through a boundary search module according to nodes with designated fixed segmentation positions;
traversing each node distributed on each programmable logic device in the initial dividing boundary, and comparing with the nodes in the modified dividing boundary one by one according to the hierarchical path of the nodes on the programmable logic device;
configuring the programmable logic device as a second programmable logic device when it is determined that there is a different node in the programmable logic device; when it is determined that there is no different node in the programmable logic device, the programmable logic device is set as the first programmable logic device.

4. The incremental segmentation processing method according to claim 1, characterized in that,
according to the comparison result between the number of different nodes and the preset node threshold and the node position distribution state of each second programmable logic device, calculate the optimal allocation between nodes and second programmable logic devices in the node position distribution state, including:
determining whether the number of different nodes in the second programmable logic device exceeds the preset node threshold;
when it is determined to be exceeded, the optimal allocation between the nodes and the second programmable logic devices in the node position distribution state is calculated by combining the node position distribution state of each second programmable logic device with the clustering division method; when it is determined that it is not exceeded, the greedy division method is adopted to combine the node position distribution state of each second programmable logic device, and calculate the optimal allocation between the node and the second programmable logic device under the node position distribution state.

5. The incremental segmentation processing method according to claim 4, characterized in that,
adopting the greedy division method to combine the node position distribution state of each second programmable logic device to calculate to obtain the optimal allocation between the nodes and the second programmable logic device in the node position distribution state, including:
obtaining the total number of second programmable logic devices and establishing a priority queue corresponding to the total number, wherein the priority queue is used for storing the initial weight of different nodes, and the initial weight is used for representing the cutting caused by the allocation of the different nodes to the second programmable logic devices;
calculating the modified weight allocated by each different node to each second programmable logic device, and replacing the stored initial weight; Allocating the different node with the smallest modification weight in the priority queue to a second programmable logic device, and deleting the different node from the priority queue;
repeatedly calculating the modified weights allocated by different nodes to the operation of the second programmable logic device, and allocating the different nodes until the different nodes are completely allocated, at this time the node layout of the second programmable logic device is optimal allocation.

6. The incremental segmentation processing method according to claim 1, characterized in that, the method further includes: controlling the second programmable logic device to execute the allocated different node according to the optimal allocation, and configuring the second programmable logic device storing the operation data for operating the modified syntax tree structure as the first programmable logic device.

7. An incremental segmentation processing apparatus characterized in that, including:
a file analysis acquisition module for acquiring an initial design file and a modified design file of a programmable logic verification array, and analyzing an initial syntax tree structure of the initial design file and a modified syntax tree structure of the modified design file;
a syntax tree running module is used for acquiring initial running data of running the initial design file in the whole process when it is determined that the difference between the initial syntax tree structure and the modified syntax tree structure is not higher than a preset increment threshold, and configuring a programmable logic device storing the initial running data as a first programmable logic device;
a comparison module for comparing the different nodes between the initial syntax tree structure and the modified syntax tree structure; The device identification module is used for identifying the first programmable logic device and the second programmable logic device in the programmable logic verification array according to the different node, and the operation data of the node in the modified syntax tree structure executed by the second programmable logic device is not saved;
a node allocation module is used for calculating the optimal allocation between the nodes and the second programmable logic devices in the node position distribution state according to the comparison result between the number of the different nodes and a preset node threshold and the node position distribution state of each second programmable logic device, and obtaining the incremental segmentation processing result

8. A computer device, including a memory and a processor, characterized in that, a computer program is stored in the memory, and the steps of the method according to claim 1 are realized when the processor executes the computer program.

9. A computer readable storage medium on which a computer program is stored, characterized in that the computer program, when executed by a processor, realizes the steps of the method according to claim 1.
